(19) United States
(12) Patent Application Publication
(10) Pub. No.: US 2005/0040740 A1
(43) Pub. Date: Feb. 24, 2005

(54) Computer

(76) Inventor: Suk-ju Yun, Suwon city (KR)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 10/923,013

(22) Filed: Aug. 23, 2004

(30) Foreign Application Priority Data
Aug. 22, 2003 (KR) 2003-58374

(51) Int. Cl. H05K 5/00

(52) U.S. Cl. 312/223.2; 361/683

(57) ABSTRACT

The present invention relates to a computer comprising a main frame and a front cover provided at the front of the main frame. A hook protrudes from the front cover toward the main frame. A locking member is adapted to slide with respect to the main frame between a hooking position at which the locking member is engaged with a hook and a releasing position at which the locking member is released from the hook. The computer includes a handle mounted on the locking member to move the locking member to the releasing position.

### CROSS-REFERENCE TO RELATED APPLICATIONS

This application claims benefit under 35 U.S.C. §119(a) from Korean Patent Application No. 2003-058374, filed on Aug. 22, 2003, in the Korean Intellectual Property Office, the disclosure of which is incorporated herein by reference in its entirety.

### BACKGROUND OF THE INVENTION

1. Field of the Invention

The present invention relates to a computer, and more particularly to a computer in which the structure for attaching a front cover is improved.

2. Description of the Related Art

Generally, a computer comprises a computer main body installed with a plurality of hardware, a monitor to which a video signal is transmitted from the computer main body to display a picture, and an input device including a keyboard connected to the computer main body to input data therein.

The computer main body typically comprises a main frame to accommodate and support a central processing unit (CPU) and a memory unit, a front cover provided at the front of the main frame to form an external appearance, and a side cover provided at the side of the main frame to form an external appearance. The computer main body can be classified according to a shape of the main frame into a desktop-type having a width longer than a length thereof, and a tower-type having a length longer than a width thereof.

In this specification, a tower type computer main body is taken as an example, but the invention is not limited thereto.

FIG. 1 is an exploded perspective view of a computer main body of a conventional computer. As shown herein, a computer main body 101 comprises a main frame 103 to accommodate and support a central processing unit (CPU) and a memory unit, a front cover 110 provided at the front of the main frame 103 to form an external appearance, and a side cover 107 provided at the side of the main frame 103 to form an external appearance.

The front cover 110 is provided with a drive installer 114 grooved to install a peripheral unit including a CD-ROM drive therein and a hooking protrusion 113 provided in a pair at upper and lower parts of a rear surface of the front cover 110, respectively.

The main frame 103 is formed with a drive accommodating part 105 to communicate with the drive installer 114 of the front cover 110 and four protrusion accommodating parts 104 to accommodate the hooking protrusions 113 of the front cover 110.

Each of the hooking protrusions 113 comprises a protrusion 113a protruding from a rear surface of the front cover 110 toward the main frame 3 and a hooking threshold 113b formed at an end part of the protrusion 113a. The protrusion 113a of the hooking protrusion 113 is inserted in the protrusion accommodating part 104 and the hooking threshold 113b prevents the protrusion 113a from coming out of the protrusion accommodating part 104, if the protrusion 113a is inserted in the protrusion accommodating part 104.

With the above configuration, to mount the front cover 110 on a front of the main frame 103, the hooking protrusion 113 of the front cover 110 should be forcibly inserted in the protrusion accommodating part 104 of the main frame 103. The hooking protrusion 113 inserted in the protrusion accommodating part 104 is prevented from coming out of the protrusion accommodating part 104, by inserting the protrusion 113a in the protrusion accommodating part 104.

However, in the conventional computer, to connect the front cover to the main frame, the hooking protrusion of the front cover should be forcedly inserted in the protrusion accommodating part of the main frame. Further, to separate the front cover from the main frame, a worker should put his hands into the main frame or between the main frame and the front cover, so that the hooking threshold is released from the protrusion accommodating part. Thus, the it can be difficult to assemble or disassemble the front cover.

### SUMMARY OF THE INVENTION

The above disadvantages are overcome and other advantages are realized in embodiments of the present invention. Accordingly, it is an aspect of the present invention to provide a computer in which the structure for attaching a front cover is improved.

It is another aspect of the present invention to provide a front cover having a hook protruding from the front cover toward the main frame, and a locking member adapted to slide with respect to the main frame. The locking member alternates between a locking position in which the locking member is engaged with a hook, and a releasing position in which the locking member is released from the hook.

Additional aspects and/or advantages of the invention will be set forth in part in the description which follows and, in part, will be obvious from the description, or may be learned by practice of the invention.

### BRIEF DESCRIPTION OF THE DRAWINGS

The above and other aspects and advantages of the present invention will become apparent and more readily appreciated from the following description of an embodiment thereof, taken in conjunction with the accompanying drawing figures, in which:

FIG. 1 is an exploded perspective view of a conventional computer;

FIG. 2 is a partial exploded perspective view of a computer according to an embodiment of the present invention;

FIG. 3 is a perspective view of a lock of the computer illustrated in FIG. 2;

FIG. 4 is an exploded perspective view of the lock of the computer illustrated in FIG. 3;

FIGS. 5 through 9 are sectional views showing how to operate the lock of the computer according to an embodiment of the present invention.

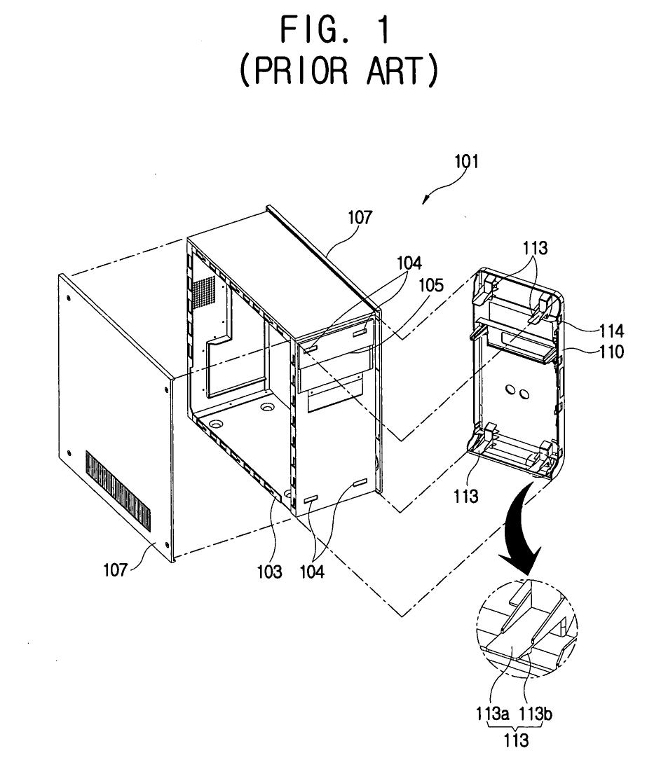

It should be understood that in the drawing figures, like reference numerals refer to like features and structures.

### DETAILED DESCRIPTION OF THE PREFERRED EMBODIMENT

Reference will now be made in detail to the following described embodiment of the present invention, features of which are illustrated in the accompanying drawings. The illustrated embodiment is described below in order to explain the present invention by referring to the drawing figures.

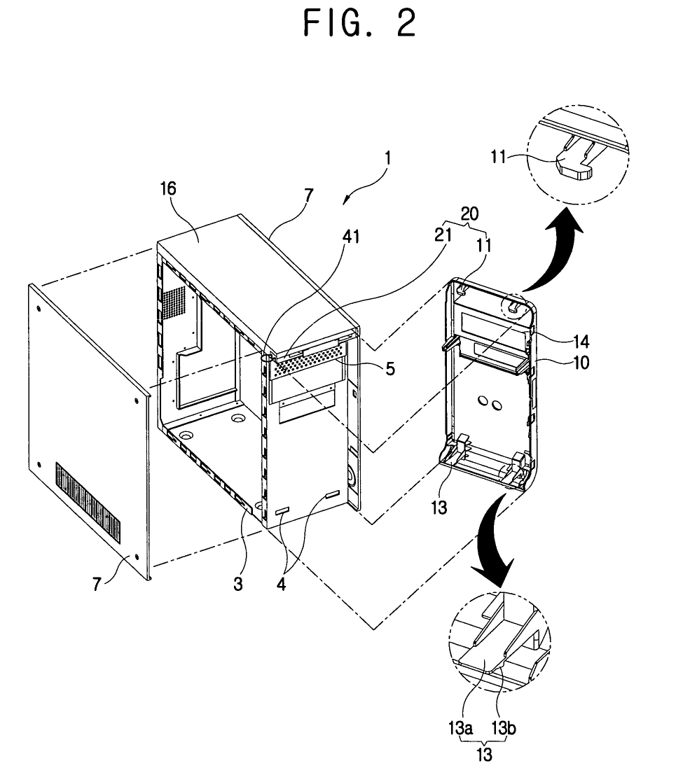

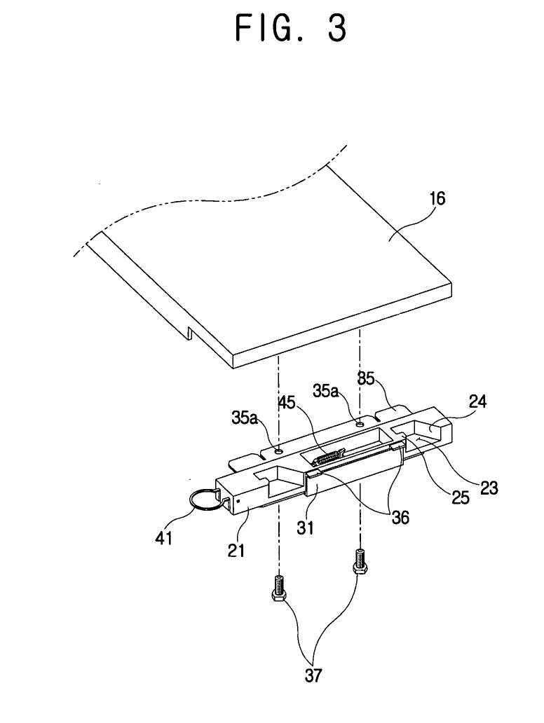

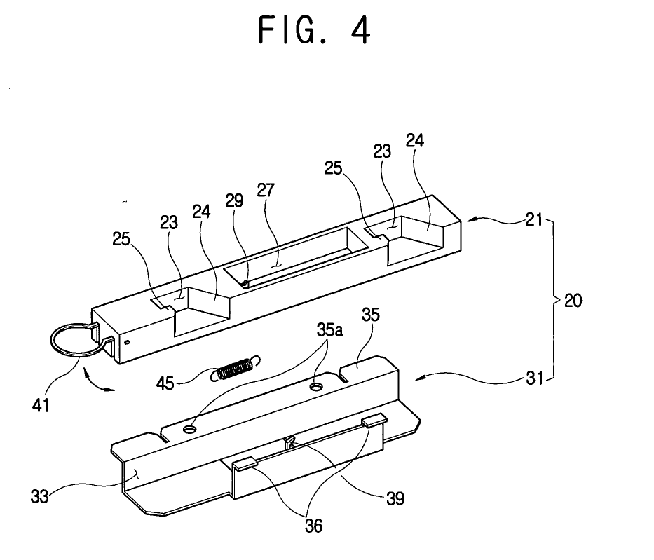

As shown in FIGS. 2 through 4, a computer according to an embodiment of the present invention comprises a computer main body 1 installed with a plurality of hardware, a monitor (not shown) to which a video signal is transmitted from the computer main body 1 to display a picture, and an input device (not shown) including a keyboard connected to the computer main body 1 to input data therein.

The computer main body 1 comprises a main frame 3 to accommodate and support a central processing unit (CPU), a memory unit and the like, a front cover 10 provided at the front of the main frame 3 to form an external appearance, a side cover 7 provided at the side of the main frame 3 to form an external appearance, a top cover 16 provided on the top of the main frame 3 to form an external appearance, and a lock 20 to connect the front cover 10 to a front of the main frame 3. The computer main body 1 is classified according to a shape of the main frame 3 into a desktop-type in which the width is longer than the length, and a tower-type in which the length is longer than the width. In the remainder of this specification, a tower-type computer main body will be described merely as an example.

The main frame 3 is installed with an internal device such as a main board (not shown) including the central processing unit (CPU) and a main memory unit. On a front of the main frame 3 a grooved driver accommodating part 5 is provided to enable installation of a peripheral unit such as a compact disk-read only memory drive (CD-ROM) (not shown) therein and at a lower part of the main frame 3 is formed a protrusion accommodating part 4 to accommodate a hooking protrusion 13 formed on a rear surface of the front cover 10 (to be described later).

The protrusion accommodating part 4 is grooved in the main frame 3 to accommodate the hooking protrusion 13 (to be described later). The protrusion accommodating part 4 is also preferably provided in a pair, each placed apart from the other on a front surface of the main frame 3.

The side cover 7 and the top cover 16 are combined to the main frame 3 by a fastener such as a screw and preferably protrude forwardly a predetermined length from a front of the main frame 3.

The front cover 10 is provided with a drive installer 14 grooved corresponding to the drive accommodating part 5 of the main frame 3 to install a peripheral unit including a CD-ROM drive therein. The hooking protrusion 13 is preferably formed at a lower part of a rear surface of the front cover 10, to be accommodated in the protrusion accommodating part 4 of the main frame 3.

The hooking protrusion 13 is preferably provided in a pair, and each of the hooking protrusions 13 is preferably placed apart from the other to be accommodated in the pair of protrusion accommodating parts 4, respectively. The hooking protrusion 13 comprises a protrusion 13a protruding from a rear surface of the front cover 10 toward the main frame 3 and a hooking threshold 13b formed under an end part of the protrusion 13a. The hooking threshold 13b prevents the hooking protrusion 13 from coming out of the protrusion accommodating part 4 by being moved downwardly and being locked to a frame of a rear surface of the protrusion accommodating part 4, when the hooking protrusion 13 is accommodated in the protrusion accommodating part 4. The area of the protrusion accommodating part 4 is preferably not smaller than those of sections of the protrusion 13a and the hooking threshold 13b, so that the hooking protrusion 13 can be accommodated in and come out of the protrusion accommodating part 4 without difficulty.

The lock 20 comprises a hook 11 protruding from a rear surface of the front cover 10 toward the main frame 3, a locking member 21 sliding with respect to the main frame 3 to be alternated between a hooking position in which the locking member 21 is engaged with the hook 11, and a releasing position in which the locking member is released from the hook 11. The lock 20 further comprises a handle 41 mounted on the locking member 21 to move the locking member 21 to the releasing position. The lock 20 preferably also comprises a locking bracket 31 to slidably support the locking member 21 and a spring 45, a side of which is connected to the locking member 21 and the other side of which is connected to the locking bracket 31.

The hook 11 protrudes from a rear surface of the front cover 10 toward the main frame 3. A protruding end part of the hook 11 is curved parallel to a surface of the front cover 10. The hook 11 is preferably provided in a pair and each of the hooks 11 are placed apart from the other at an upper part of a rear surface of the front cover 10. The end part of the hook 11 is preferably inclined to slidably contact with an inclined part 24 of the hook accommodating part 23 and the locking part 25 with ease, when the hook 11 is inserted in and comes out of the hook accommodating part 23.

The locking member 21 is preferably provided in a long plate shape and comprises: the hook accommodating part 23 to accommodate the hook 11, and a locking part 25 connected with the hook 11 accommodated in the hook accommodating part 23 to prevent the hook 11 from coming out of the hook accommodating part 23. The locking member 21 is guided by a locking bracket 31 in order to slide along a transverse direction with respect to the main frame 3. The locking member 21 preferably comprises a groove 27 to accommodate the spring 45 on a surface thereof and a first spring support 29 to connect and support a side of the spring 45.

The hook accommodating part 23 is preferably provided in a pair to accommodate the pair of hooks 11, respectively. The hook accommodating part 23 is formed with an inclined part 24 to contact with the hook 11 and to make the hook 11 come out of the hook accommodating part 23, when the locking member 21 is at the releasing position. That is, at a side of the hook accommodating part 23 is provided an inclined part 24 described above to push the inserted hook 11 forwardly and at the other side is preferably provided the locking part 25 described above.

The locking part 25 protrudes at the other side of the hook accommodating part 24 to be hooked with the hook 11. A front surface of the locking part 25 is preferably inclined to contact with the hook 11, when the hook is inserted in the hook accommodating part 23, so that the hook 11 pushes the locking member 21 and is inserted in the hook accommodating part 23.

The locking bracket 31 comprises a locking member guide 33 to accommodate and guide the locking member 21 and is preferably connected to the top cover 16 as a single body with the top cover 16. The locking bracket 31 is provided in a plate shape and comprises a first combining bracket 35 and a second combining bracket 36 at opposite sides of a direction transverse to a sliding direction of the locking member 21 to combine to a front bottom surface of the top cover 16. The locking bracket 31 is preferably provided with a second spring support 39 inserted in the groove 27 of the locking member 21 to connect to the other side of the spring 45.

The surface of the locking bracket 31 is preferably curved to have a ‘τ’ shape, thereby enabling to accommodate and guide the locking member 21.

A side of the locking member guide 33 is curved parallel to a surface of the top cover 16 to form the first connecting bracket 35. The first connecting bracket 35 is formed with a plurality of connecting holes 35a to be connected to a bottom surface of the top cover by a screw 37.

The other side of the locking member guide 33 is curved parallel to the top cover 16 to form the second connecting bracket 35 to be inserted in the inserting part (not shown) formed at a bottom surface of the top cover 16. The second connecting bracket 36 is preferably formed in duplicate.

The handle 41 is preferably mounted on a side of the locking member 21 to move the locking member 21 to the releasing position. The handle 41 has a ring shape convenient for a user to grip it and can preferably be folded on the locking member 21.

A side of the spring 45 is combined with the first spring support 29 of the locking member 21 and the other side thereof is connected with the second spring support 39 of the locking bracket 31, thereby supplying the elastic force by which the locking member 21 returns to the hooking position, when the locking member 21 moves to the releasing position. The spring is preferably a pressed coil spring.

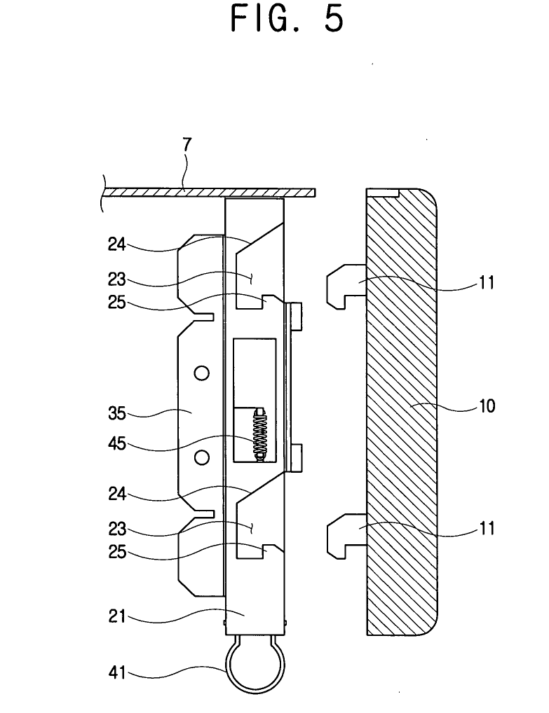

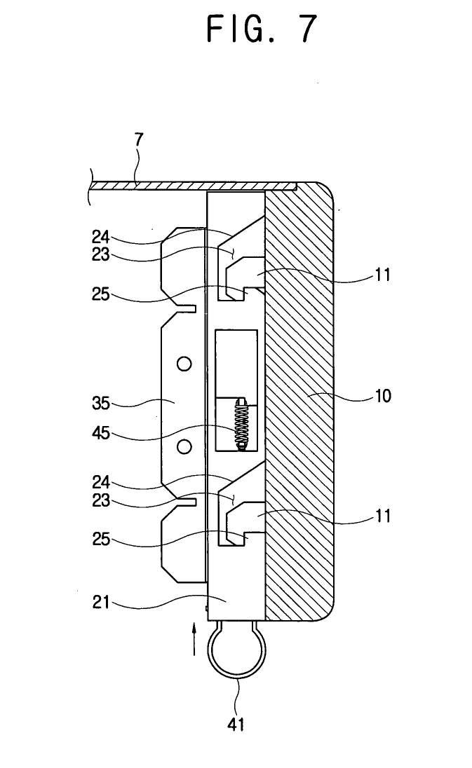

With the above configuration, the lock 20 of the computer according to the embodiment of the present invention is operated as follows (refer to FIGS. 5 through 8).

First, the front cover 10 is mounted on the main frame 3 as follows.

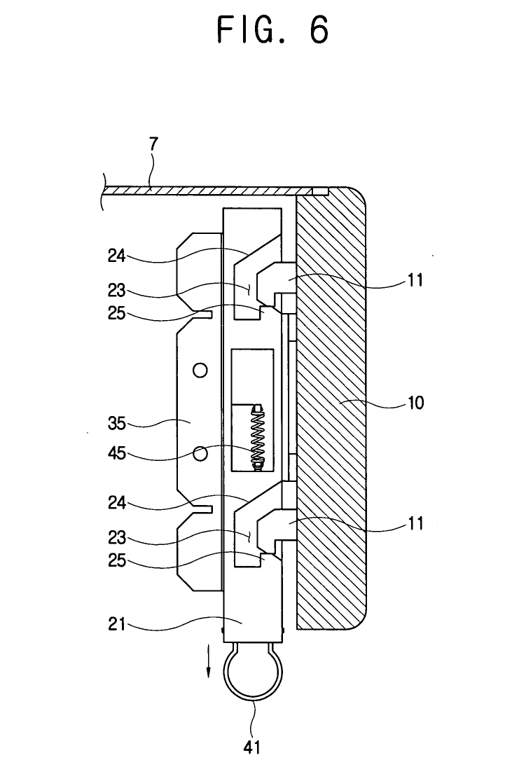

The hooking protrusion 13 provided at a lower part of the front cover 10 is inserted in the protrusion accommodating part 4 of the main frame 3. Then, the front cover 10 is moved down a predetermined length, so that the hooking threshold 13b of the hooking protrusion 13 is locked to the frame of the rear surface of the protrusion accommodating part 4. Next, the hook 11 provided at the upper part of the front cover 10 is inserted in the hook accommodating part 23 of the locking member 21 (refer to FIG. 5). The end part of the hook 11 contacts the locking part 25 and overcomes the elasticity of the spring 45, thereby pushing the locking member 21 in a direction transverse to the insertion direction of the hook 11 (refer FIG. 6). Thereafter, if the hook 11 is completely inserted in the hook accommodating part 23, the locking member 21 returns to the hooking position by the elasticity of the spring 45, thereby being held in the locking part 25 and preventing the hook 11 from coming out of the hook accommodating part 23.

Then, the front cover 10 is separated from the main frame 3 as follows.

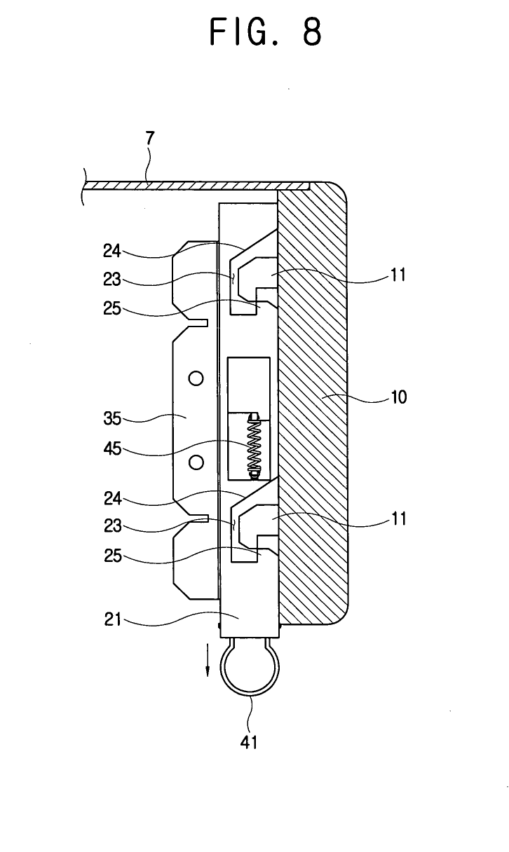

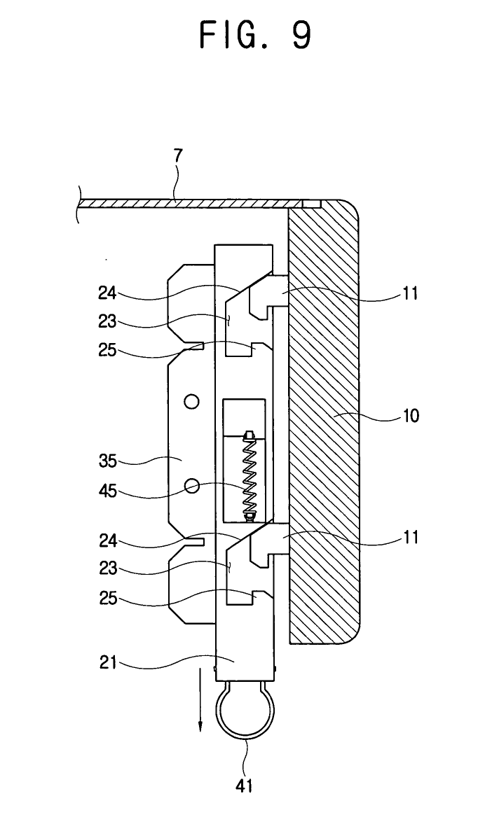

First, the handle 41 mounted on a side of the locking member 21 is pulled in a direction along which the locking part 21 is released from the hook 11, by overcoming the elasticity of the spring 45. Then, the locking part 25 is released from the hook 11 (refer to FIG. 8). If the handle 41 is pulled further, the inclined part 24 provided in the hook accommodating part 23 contacts to the hook 11 and pushes the hook 11 forwardly, thereby causing the hook 11 to come out of the hooking accommodating part 23 (refer to FIG. 9). Thereafter, the protrusion 13 comes out of the protrusion accommodating part 4, so that the front cover 10 is completely separated from the main frame 3.

In the embodiment described above, the hook and the locking member are mounted at upper parts of the front cover and the main frame, but the hook and the locking member may be mounted at lower parts of the front cover and the main frame.

As described above, a computer according to an embodiment of the present invention provides the hook mounted on the front cover, the locking member sliding with respect to the main frame to be engaged with and released from the hook, and the handle mounted on the locking member to move the locking member to the releasing position, so that the front cover can be assembled and disassembled with ease.

Although an exemplary embodiment of the present invention has been shown and described, it will be appreciated by those skilled in the art that changes may be made in this embodiment without departing from the principles and spirit of the invention, the scope of which is defined in the appended claims, and equivalents thereof.

1. A computer comprising a main frame and a front cover provided at the front of the main frame, the computer comprising:
a hook protruding from the front cover toward the main frame;
a locking member adapted to slide with respect to the main frame between a hooking position at which the locking member is engaged with the hook and a releasing position at which the locking member is released from the hook.

2. The computer according to claim 1, further comprising a handle mounted on the locking member to move the locking member to the releasing position.

3. The computer according to claim 1, further comprising a locking bracket slidably supporting the locking member.

4. The computer according to claim 1, wherein the locking member comprises a hook accommodating part accommodating the hook and a locking part connected with the hook accommodated in the hook accommodating part and preventing the hook from coming out of the hook accommodating part.

5. The computer according to claim 4, wherein the hook accommodating part is formed with an inclined part adapted to contact the hook and to cause the hook to come out of the hook accommodating part when the locking member is at the releasing position.

6. The computer according to claim 3, wherein the locking bracket further comprises a locking member guide adapted to accommodate and guide the locking member.

7. The computer according to claim 3, further comprising a spring a first side of which is connected to the locking member and a second side of which is connected to the locking bracket.

8. The computer according to claim 3, further comprising a top cover provided on the top of the main frame, wherein the locking bracket being is adapted to be connected to the top cover as a single body with the top cover.

9. The computer according to claim 4, wherein the hook is provided in a pair on an upper part of the front cover and the hook accommodating part and the locking member are provided in respective pairs corresponding to the pair of hooks.

10. The computer according to claim 1, wherein the front cover is further provided with a hooking protrusion protruding toward the main frame and placed apart from the hook, and wherein the main frame is further formed with a protrusion accommodating part adapted to accommodate the hooking protrusion.

11. The computer according to claim 10, wherein the hooking protrusion is provided in a pair at a lower part of the front cover and the protrusion accommodating part is provided in a pair adapted to correspond to the pair of hooking protrusions.

12. The computer according to claim 4, wherein the front cover is further provided with a hooking protrusion protruding toward the main frame and placed apart from the hook and the main frame is further formed with a protrusion accommodating part for accommodating the hooking protrusion.

13. The computer according to claim 7, wherein the front cover is further provided with a hooking protrusion protruding toward the main frame and placed apart from the hook and the main frame is further formed with a protrusion accommodating part for accommodating the hooking protrusion.
